(19) United States
(12) Patent Application Publication
(10) Pub. No.: US 2016/0307818 A1
(43) Pub. Date: Oct. 20, 2016

(54) SEMICONDUCTOR DEVICE HAVING A HEAT CONDUCTION MEMBER

(71) Applicant: KABUSHIKI KAISHA TOSHIBA, Tokyo (JP)

(72) Inventors: Masayasu KAWASE, Yokohama Kanagawa (JP); Masato SUGITA, Yokohama Kanagawa (JP)

(21) Appl. No.: 14/837,980

(22) Filed: Aug. 27, 2015

(30) Foreign Application Priority Data
Apr. 20, 2015 (JP) 2015-086154

(51) Int. Cl. H01L 23/367

(52) U.S. Cl. CPC H01L 23/3675

(57) ABSTRACT

A semiconductor device includes a substrate having a first surface and a second surface opposite to the first surface, a hole formed through the first and second surfaces of the substrate, a semiconductor element disposed on the first surface to cover the hole, a housing in which the substrate and the semiconductor element are housed, and a heat conduction member disposed in the hole, such that heat generated by the semiconductor element is transferred through the heat conduction member towards a portion of the housing facing the second surface of the substrate.

### CROSS-REFERENCE TO RELATED APPLICATION

This application is based upon and claims the benefit of priority from Japanese Patent Application No. 2015-086154, filed Apr. 20, 2015, the entire contents of which are incorporated herein by reference.

### FIELD

Embodiments described herein relate generally to a semiconductor device, in particular, a semiconductor device having a heat conduction member.

### BACKGROUND

A semiconductor device having a heat radiation structure is known.

### DESCRIPTION OF THE DRAWINGS

FIG. 1 is a perspective view of a semiconductor device according to a first embodiment.

FIG. 2 is a block diagram of functional units included in the semiconductor device of FIG. 1.

FIG. 3 is a cross-sectional view of the semiconductor device according to the first embodiment.

FIG. 4 is a plan view a heat conduction pad of a control unit included in the semiconductor device according to the first embodiment.

FIGS. 5 and 6 are each a plan view of the heat conduction pad according to other examples

FIG. 7 is a cross-sectional view of a semiconductor device according to a second embodiment.

FIG. 8 is a cross-sectional view of a semiconductor device according to a third embodiment.

FIG. 9 is a perspective view of a semiconductor device according to a fourth embodiment.

FIG. 10 is a cross-sectional view of the semiconductor device according to the fourth embodiment.

FIG. 11 is a perspective view of a heat conduction member used in the semiconductor device according to the fourth embodiment.

FIG. 12 is a cross-sectional view of a semiconductor device according to a fifth embodiment.

### DETAILED DESCRIPTION

A semiconductor device according to an embodiment has improved heat radiation efficiency.

In general, according to an embodiment, a semiconductor device includes a substrate having a first surface and a second surface opposite to the first surface, a hole formed through the first and second surfaces of the substrate, a semiconductor element disposed on the first surface to cover the hole, a housing in which the substrate and the semiconductor element are housed, and a heat conduction member disposed in the hole, such that heat generated by the semiconductor element is transferred through the heat conduction member towards a portion of the housing facing the second surface of the substrate.

Semiconductor devices according to the following plurality of exemplary embodiments and a modification example may include the same components.

In the present disclosure, several components are denoted by plural expressions. These expressions are examples and may be indicated by other expressions. In addition, components which are not denoted by plural expression examples may be indicated by other expressions.

In addition, drawings are schematic, and a relationship between a thickness and a planar dimension, a ratio of the thickness of each layer, and the like may be different from the actual ones. In addition, the drawings may include portions different from each other in dimensional relationship and ratio.

### First Embodiment

A semiconductor device 130 according to a first embodiment is, for example, a solid state drive (SSD) device, and is a large-capacity data storage device that uses a nonvolatile semiconductor memory such as a NAND-type flash memory. The semiconductor device 130 includes a case 12 (a housing, a casing, a cover) as an example. In the semiconductor device, a first substrate 14 (a printed wiring board (PWB), a raw substrate, a motherboard) is fixed to the inside of the case 12. The first substrate 14 includes at least one element (a semiconductor component, an electronic component, a package component).

The element 16 includes a second substrate 18 (a PWB, a raw substrate, a bare board), at least one storage unit 20 (a first electronic component, a storage chip, a NAND-type flash memory chip, an Si chip, a die) which is provided on the second substrate 18, and a control unit 22 (a second electronic component, a control chip, a controller, an Si chip, a die) which controls the storage unit 20. The element 16 configures a so-called one package SSD, which is capable of independently functioning as a storage device. In addition, the element 16 is a so-called “bare chip” in which the storage unit 20 and the control unit 22 are not coated with a resin.

By using a flip-chip mounting of the control unit 22 and the storage unit 20 on the second substrate 18, the size (thickness) of the element 16 can be reduced. As a result, it is possible to reduce the size (thickness) of the semiconductor device 130 on which the element 16 is mounted.

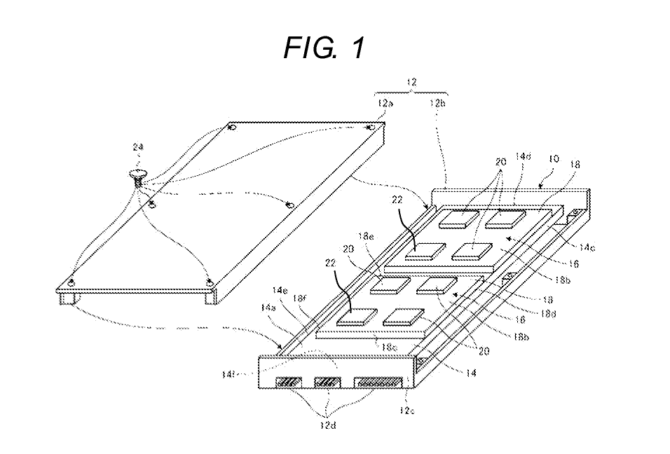

Meanwhile, in the semiconductor device 130 illustrated in FIG. 1, a plurality of elements 16 is provided on the first substrate 14 that is fixed inside of the case 12, so that the storage capacity of the entire semiconductor device 130 is increased. In FIG. 1, the first substrate 14 includes two elements 16, but the number of elements 16 may be appropriately selected in accordance with storage capacity required for the semiconductor device 130. For example, the number of elements may be one or may be three or more.

The case 12 includes, for example, a first cover 12a (an upper cover, a lid, an upper casing) and a second cover 12b (a lower cover, a case main body, a lower casing). The first cover 12a and the second cover 12b are combined with each other in a state where the first substrate 14 is fixed to a mounting region of the second cover 12b, and thus are fixed by a fastening member 24 (a screw, a bolt, a clip).

The first substrate 14 and the element 16 (second substrate 18, storage unit 20, control unit 22) are covered with the case 12, so that the first substrate 14 and the element 16 are protected from an external force applied to the semiconductor device 130. In other words, it is possible to improve the protection performance of the semiconductor device 130 and to improve dustproof performance. Meanwhile, in FIG. 1, for example, six screws are shown as the fastening members 24, but the number of fastening members 24 may be appropriately determined. For example, when the first cover 12a and the second cover 12b include coupling units that are engaged with each other, the first cover 12a and the second cover 12b may be fixed using one screw or two screws in a state in which the coupling state between the coupling units is maintained.

In the semiconductor device 130, for example, an outer surface 12c of the second cover 12b has a case connector 12d for electrically connecting the semiconductor device 130 to an external device (not shown), transferring data to and from the external device, and receiving power from the external device. Although not shown in FIG. 1, the first substrate 14 has an internal connector which is electrically connected to the case connector 12d. The case connector 12d may be appropriately modified according to the use of the semiconductor device 130.

For example, when the semiconductor device 130 is a built-in type which is connected to a motherboard and the like within a computer, the case connector 12d may include a pin connector which includes a plurality of pins as illustrated in FIG. 1. When the semiconductor device 130 is an external type which is externally connected to a computer, the case connector 12d may include a universal serial bus (USB) and a power terminal instead of the pin connector.

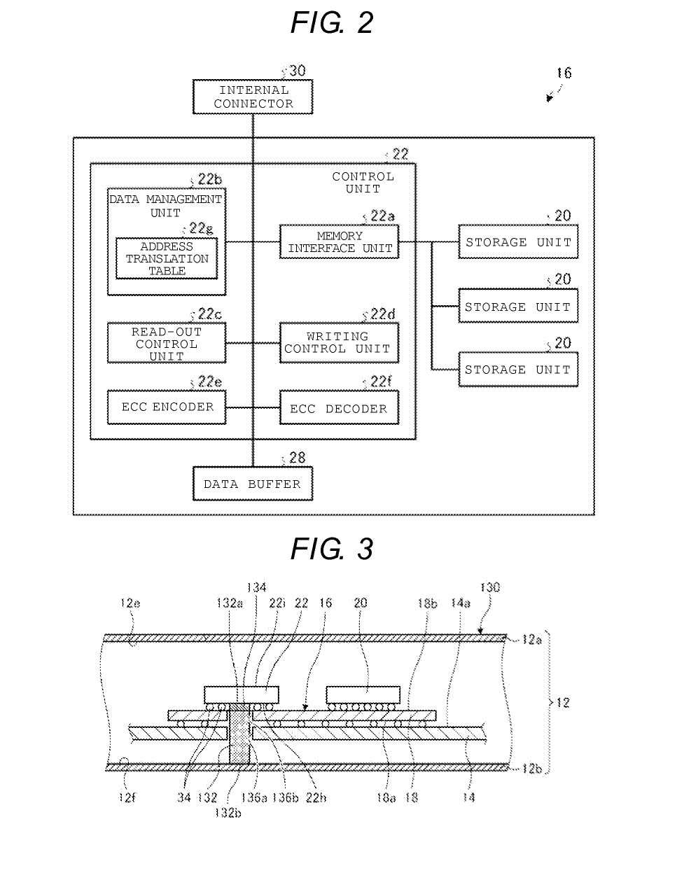

FIG. 2 is a block diagram of functional units of the element 16 in the semiconductor device 130 illustrated in FIG. 1. The storage unit 20 is a nonvolatile memory, and is, for example, a NAND-type flash memory. The storage unit 20 is not limited to the NAND-type flash memory, and may be a resistance random access memory (RERAM), a ferroelectric random access memory (FERAM), or the like.

The storage unit 20 stores user data which is transmitted from the outside (host device) of the semiconductor device 130, system data which is used only within the element 16, and the like. In FIG. 1, a plurality of storage units 20 is arrayed and fixed onto the second substrate 18. Specifically, in FIG. 1, as an example, three storage units 20 are fixed onto each of the second substrates 18. The number of storage units 20 fixed onto the second substrate 18 may vary according to storage capacity required for the semiconductor device 130 and may be one or two. In addition, the number of storage units may be four or more. The individual storage units 20 may store binary data or multi-value data.

A data buffer 28 temporarily stores data. The data buffer 28 is, for example, a dynamic random access memory (DRAM). The data buffer 28 is not limited to the DRAM, and may be a static random access memory (SRAM) or the like. The data buffer 28 may be provided independently of the control unit 22, or may be mounted as an incorporated type memory within the control unit 22.

The control unit 22 controls the storage unit 20. For example, the functions of the control unit 22 may be achieved by a processor that executes firmware stored in a read only memory (ROM) included in the storage unit 20 or the control unit 22, hardware, or the like. The control unit 22 reads out data from the storage unit 20 and writes data in the storage unit 20 in response to a command from a host device.

In addition, the control unit 22 includes, for example, a memory interface unit 22a (memory I/F unit), a data management unit 22b, a read-out control unit 22c, a writing control unit 22d, an ECC encoder 22e, an ECC decoder 22f, and the like.

The memory interface unit 22a writes a code word, which is input from the ECC encoder 22e, under the control of the writing control unit 22d and the like in the storage unit 20. In addition, the memory interface unit 22a reads out the code word from the storage unit 20 under the control of the read-out control unit 22c and the like, and transmits the read code word to the ECC decoder 22f.

The data management unit 22b determines where to store data on the storage unit 20. The data management unit 22b stores an address translation table 22g in which a logic address given from a host device is associated with a physical location on the storage unit 20 and performs garbage collection in accordance with usage conditions of blocks of the storage unit 20.

The read-out control unit 22c performs processing for reading out data from the storage unit 20 in response to a command notified from the host device through an internal connector 30. Specifically, the read-out control unit 22c acquires the physical location on the storage unit 20 which corresponds to the logic address of the read data from the data management unit 22b and notifies the memory interface unit 22a of the physical location. The read-out data is transmitted toward the host device through the ECC decoder 22f, the data buffer 28, and the like.

The writing control unit 22d performs processing for writing data in the storage unit 20 in response to the command notified from the host device through the internal connector 30. Specifically, the writing control unit 22d acquires the physical location on the storage unit 20 in which data is to be written, from the data management unit 22b, and outputs the physical location and the code word which is output from the ECC encoder 22e, to the memory interface unit 22a.

The ECC encoder 22e encodes data stored in the data buffer 28 to thereby generate a code word having data and a redundant portion (parity). The ECC decoder 22f acquires the code word which is read out from the storage unit 20, from the memory interface unit 22a, and decodes the acquired code word. The ECC decoder 22f notifies the read-out control unit 22c of a read error when failing in error correction during the decoding.

Incidentally, the amount of heat generated in the control unit 22 increases in response to an increase in a frequency used by the control unit 22, which may heat the control unit 22 and the surrounding components. Therefore, the effective heat radiation of the control unit 22 may suppress deterioration in functions and a reduction in the life span of the control unit 22 and the adjacent storage unit 20 due to heat.

Consequently, the semiconductor device 130 according to the present embodiment has a first heat conduction member 132, and is thermally connected (adhered) to, for example, the second cover 12b of the case 12 through the first heat conduction member 132. In addition, the phrase “thermally connected” used in the present embodiment refers to a configuration in which heat conduction is performed, for example, through a medium having thermal conductivity higher than that of air (outside air). In other words, the direction of heat flow is controlled, and a direct contact may not be necessary.

FIG. 3 is a cross-sectional view of the semiconductor device 130 according to the first embodiment. In particular, FIG. 3 illustrates an enlarged cross-sectional view of the element 16. As illustrated in FIGS. 1 and 3, the first substrate 14 mounted in the case 12 is a flat plate-shaped component including a first surface 14a (a first surface, a mounting surface, a first substrate surface, an upper surface), a rear surface 14b (a lower surface, a rear surface, a bottom surface) opposite to the first surface 14a, and side surfaces 14c, 14d, 14e, and 14f.

Although not shown in FIG. 3, the first substrate 14 has a multi-layered structure, for example, an eight-layered structure which is formed by layering a plurality of synthetic resin layers. Various shaped-wiring patterns are formed on the surface of each layer. For example, a signal layer that performs transmission and reception of a signal, a ground layer, a power supply layer, and the like are formed. Here, the number of layers of the first substrate 14 is not limited to eight. In addition, the type of wiring pattern of each layer may be appropriately changed. For example, different types of wiring patterns may be formed in the same layer, or a layer having no wiring pattern may be formed.

In another embodiment, the first substrate 14 may be a single-sided substrate (single-layered substrate) or a double-sided substrate (two-layered substrate). When the first substrate 14 is a single-sided substrate, a ground pattern, a signal pattern, a power supply pattern, or the like is formed in the first surface 14a. In addition, when the first substrate 14 is a double-sided substrate, a ground pattern, a signal pattern, a power supply pattern, and the like are formed in the first surface 14a and the rear surface 14b by being appropriately distributed. The side surface 14f of the first substrate 14 includes an internal connector 30 (an interface, a serial ATA (SATA), a connection plug, see FIG. 2) connected to the case connector 12d. The signal layer, the ground layer, the power supply layer, and the like, not shown in FIG. 3, which are formed in the inner layer of the first substrate 14 are electrically connected to a predetermined terminal pin of the internal connector 30 and further to the case connector 12d.

The element 16 configuring one package SSD is formed on the first surface 14a of the first substrate 14. As illustrated in FIG. 3, the element 16 includes the second substrate 18 (a package substrate or a BGA substrate), the control unit 22, and the storage unit 20. The element 16 is a bare chip semiconductor in which a bare chip having no covering portion (mold, reinforcement, cover) which covers the control unit 22 and the storage unit 20 as described above is mounted on the second substrate 18. The element 16 is electrically connected and fixed to the first surface 14a of the first substrate 14 through a bump 32 (solder bump).

The second substrate 18 has a second surface 18a (lower surface, rear surface, bottom surface) which faces the first surface 14a and a third surface 18b (third surface, mounting surface, third substrate surface, upper surface, surface, top face) opposite to the second surface 18a. In addition, as illustrated in FIG. 1, the second substrate 18 has a flat plate-shaped and includes side surfaces 18c, 18d, 18e, and 18f. Although not shown in FIG. 3, the second substrate 18 has a multi-layered structure which is formed by layering a plurality of synthetic resin layers, similar to the first substrate 14. Various shaped-wiring patterns are formed in the surface of each layer of the second substrate 18. For example, a signal layer that performs transmission and reception of a signal, a ground layer, a power supply layer, and the like are formed.

The control unit 22, which is a bare chip, is, for example, a flat rectangular parallelepiped component as illustrated in FIG. 1. The control unit includes a fourth surface 22h (lower surface, rear surface, bottom surface) on which a bump 34 (solder bump) for electrical connection to the third surface 18b is formed, and a fifth surface 22i (upper surface, surface, top face) opposite to the fourth surface 22h.

Similarly, the storage unit 20, which is a bare chip component, is, for example, a flat rectangular parallelepiped component as illustrated in FIG. 1. The storage unit 20 includes a sixth surface 20a (lower surface, rear surface, bottom surface) in which the bump 34 for electrical connection to the third surface 18b is formed, and a seventh surface 20b (upper surface, surface, top face) opposite to the sixth surface 20a.

The control unit 22 and the storage unit 20 are electrically connected to the third surface 18b of the second substrate 18 through the bump 34, for example, by flip-chip mounting, and are mechanically connected thereto.

Meanwhile, as illustrated in FIG. 1, the control unit 22 is arranged, for example, at a location close to a corner where the side surface 18c and the side surface 18f intersect each other on the third surface 18b. In addition, three storage units 20 are arranged at a location close to a corner where the side surface 18c and the side surface 18d intersect each other, at a location close to a corner where the side surface 18d and the side surface 18e intersect each other, and at a location close to a corner where the side surface 18e and the side surface 18f intersect each other. The elements 16 are arranged on the first surface 14a of the first substrate 14 so that the control units 22 are not adjacent to each other, as illustrated in FIG. 1.

In this manner, the control units 22 are arranged so as not to be adjacent to each other. Heat generated at the control units 22 transfers through the first heat conduction members 132 that are in contact with the control units 22 and dispersed in the second cover 12b. As a result, it is possible to improve the efficiency of heat radiation from the second cover 12b.

The semiconductor device 130 according to the present embodiment has the first heat conduction member 132 as described above, and is thermally connected (adhered) to, for example, the second cover 12b of the case 12 through the first heat conduction member 132. That is, the case 12 has a first wall 12e (wall of the first cover 12a) and a second wall 12f (wall of the second cover 12b) which faces the first wall 12e and is in contact with the first heat conduction member 132.

The first heat conduction member 132 passes through the first substrate 14 and is thermally connected (adhered) to the second wall 12f. That is, the first heat conduction member 132 is, for example, a rod-like member including a tenth surface 132a which is thermally connected to a heat conduction pad 134 formed on the fourth surface 22h of the control unit 22, and an eleventh surface 132b which is opposite to the tenth surface and thermally connected to the second wall 12f of the second cover 12b.

The first heat conduction member 132 passing through the first substrate 14 and the second substrate 18 may transfer heat generated in the control unit 22 toward the second cover 12b through the fourth surface 22h while restraining the heat from being transferred to the first substrate 14 and the second substrate 18.

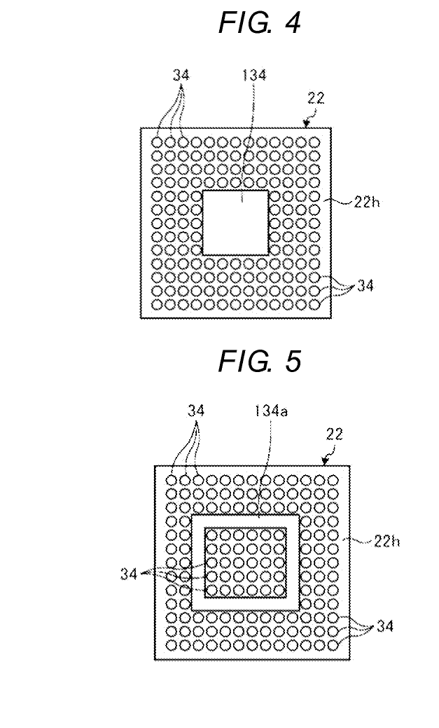

FIG. 4 is a plan view of the control unit 22 seen from the fourth surface 22h, and illustrates the shape of the heat conduction pad 134 which is thermally connected (adhered) to the first heat conduction member 132. In FIG. 4, the heat conduction pad 134 has a square shape, for example, and is disposed in the central region of the fourth surface 22h. The heat conduction pad 134 may be formed of metal with high thermal conductivity such as copper. Meanwhile, a plurality of bumps 34 for transferring a signal to and from the control unit 22 is arrayed in the vicinity of the heat conduction pad 134, and may be electrically connected to the third surface 18b of the second substrate 18.

The shape of the heat conduction pad 134 is not limited to a square shape illustrated in FIG. 4. For example, the heat conduction pad may be a rectangular frame-shaped heat conduction pad 134a as illustrated in FIG. 5. In this case, the bumps 34 may be arranged on the inner side of the rectangular frame-shaped heat conduction pad 134a. For example, when it is necessary to dispose the bumps 34 in the central region of the fourth surface 22h for reasons of the configuration of the control unit 22, such a rectangular frame-shaped heat conduction pad 134a may be adopted.

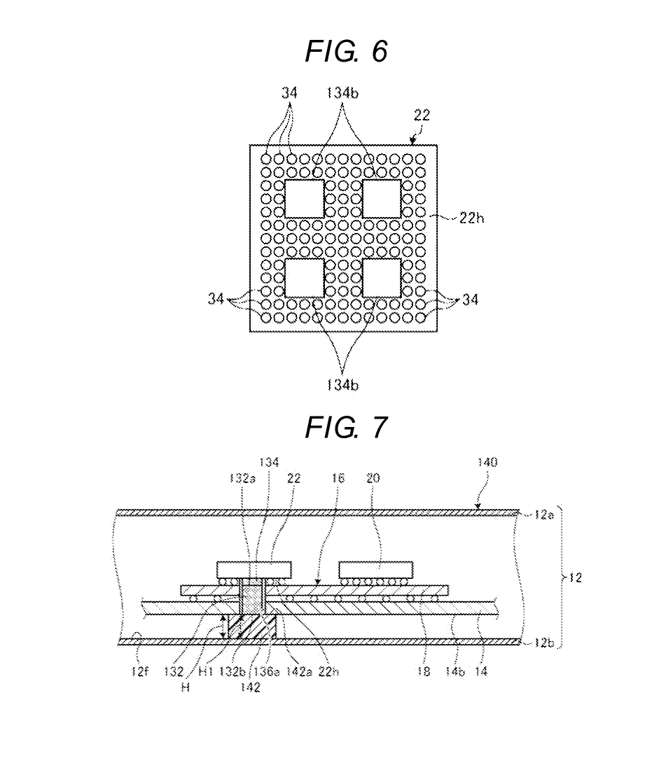

In addition, as illustrated in FIG. 6, a plurality of (four in FIG. 6) square-shaped heat conduction pads 134b having a smaller size than the heat conduction pad 134 illustrated in FIG. 4 may be arranged. In this case, when locations where the bumps 34 are arranged in the fourth surface 22h are determined for reasons of the configuration of the control unit 22, the heat conduction pads 134b may be arranged by avoiding the locations of the bumps 34.

In the present embodiment, the heat conduction pad 134 (134b) may thermally connect at least the first heat conduction member 132 and the control unit 22. In addition, when the second cover 12b (case) and the control unit 22 are thermally connected to each other through the first heat conduction member 132, the heat conduction pad 134 (134b) may not be necessary.

In addition, the heat conduction pad 134 may be arranged so as to be offset towards the storage unit 20. In other words, the heat conduction pad 134 may be located at a region between the center of the control unit 22 and the storage unit 20. Here, “the center of the control unit 22” refers to a location where distances from the individual side surfaces except for the fourth surface 22h and the fifth surface 22i of the control unit 22 are equal to each other. In general, a memory I/F unit 22a is arranged at a position close to the storage unit 20 in the control unit 22. This is for the purpose of reducing a wiring distance between the storage unit 20 and the memory I/F unit 22a in the second substrate 18.

When the memory I/F unit 22a is not arranged so as to be offset towards the storage unit 20, the wiring distance between the storage unit 20 and the memory I/F unit 22a increases, and thus parasitic capacitance, parasitic resistance, parasitic inductance, and the like increase, which results in a difficulty in maintaining the characteristic impedance of a signal wiring. This also results in signal delay.

Therefore, the memory I/F unit 22a is generally arranged so as to be offset towards the storage unit 20 in the control unit 22. Further, in the control unit 22, the temperature of a portion at which the memory I/F unit 22a is located tends to rise. This is because the control unit 22 (memory I/F unit 22a) mainly operates for data exchange between the storage unit 20 and the control unit 22, or the like.

According to the present embodiment, a heat radiation path is provided at a location close to a region in which a largest amount of heat is generated in the control unit 22 by arranging the heat conduction pad 134 so as to be offset towards the storage unit 20. As a result, it is possible to more efficiently perform heat radiation in the control unit 22. Here, the heat conduction pads 134, 134a, and 134b may not be necessary. When the heat conduction pads 134, 134a, and 134b are not disposed, the first heat conduction member 132 abutting on the control unit 22 is arranged in a position close to the storage unit 20, which results in the same effects.

The area of the heat conduction pads 134, 134a, and 134b functioning as heat conduction paths may be appropriately determined on the basis of heat conduction efficiency, the occupancy area of the bumps 34, the arrangement of the bumps 34, and the like. The shapes and arrangement of the heat conduction pads 134, 134a, and 134b illustrated in FIGS. 4 to 6 are merely examples and may be appropriately modified. For example, the shape of the heat conduction pad 134 may be a circular shape or a triangular shape.

Referring back to FIG. 3, the first heat conduction member 132 conducts heat and may be formed of, for example, a synthetic resin material (silicone rubber, elastomer, flexible resin) or metal having high thermal conductivity such as copper. When the first heat conduction member 132 is formed of a synthetic resin, the first heat conduction member 132 may have flexibility and may be disposed between the heat conduction pad 134 and the second wall 12f of the second cover 12b in a compressed state.

In other words, the dimension of the first heat conduction member 132 in the thickness direction (insertion direction) in a free state where the first heat conduction member is not held between the heat conduction pad 134 (element, control unit) and the second cover 12b (case) is larger than the dimension thereof in the thickness direction (insertion direction) when the first heat conduction member is held between the heat conduction pad 134 (element) and the second cover 12b (case). In this case, the first heat conduction member 132 adheres to the respective surfaces of the heat conduction pad 134 and the second wall 12f, which improves heat transfer efficiency.

In addition, the first heat conduction member 132 itself may have an adhesive property (adhesive force). In this case, the first heat conduction member 132 may be temporarily fixed (attached) to at least one of the second cover 12b or the heat conduction pad 134 (element, control unit) while assembling the semiconductor device 130. As a result, it is possible to improve assembling efficiency.

Meanwhile, the adhesiveness (adhesive force) may be maintained for a period of time necessary for at least the assembling, or alternatively the adhesive force may be maintained permanently. In addition, the adhesive force may be an adhesive force to such an extent that the first heat conduction member 132 may be easily attached and released. In this case, as positioning while temporarily fixing the first heat conduction member 132 and the repositioning thereof are facilitated, it is possible to improve workability.

In addition, when the first heat conduction member 132 is formed of a rod-like member of metal such as copper, a connection portion between the first heat conduction member 132 and the heat conduction pad 134 and a connection portion between the first heat conduction member 132 and the second wall 12f may be thermally and mechanically connected using a bonding material such as solder. It is possible to improve the efficiency of heat transfer through the first heat conduction member 132 by performing the connection mechanically. Meanwhile, the shape of the first heat conduction member 132 may be a rectangular parallelepiped shape according to the shapes of the heat conduction pads 134 and 134b or may be a square tubular shape according to the shape of the heat conduction pad 134a.

In addition, a protrusion may be provided in a portion of the casing, and the protrusion may serve as a heat radiation path in the control unit 22. Accordingly, the first heat conduction member 132 may be formed integrally with, for example, the second cover 12b (case).

Incidentally, when heat generated in the control unit 22 is transferred towards the second cover 12b through the first heat conduction member 132, the physical contact between the first heat conduction member 132 and the first substrate 14 or the second substrate 18 may cause the heat to be transferred to the first substrate 14 or the second substrate 18.

In the present embodiment, when the first heat conduction member 132 passes through the first substrate 14, a through hole 136a that is larger than the first heat conduction member 132 (i.e., does not contact first heat conduction member 132) is formed in the first substrate 14. Similarly, when the first heat conduction member 132 passes through the second substrate 18, a through hole 136b that is larger than the first heat conduction member 132 (i.e., does not contact the first heat conduction member 132) is formed in the second substrate 18.

In this manner, when the first heat conduction member 132 is inserted through the first substrate 14, an air layer (space) is formed between the wall of the through hole 136a and the outer surface (side surface) of the first heat conduction member 132. As a result, it is possible to restrain heat transferred through the first heat conduction member 132 from being transferred to the first substrate 14.

Similarly, when the first heat conduction member 132 is inserted through the second substrate 18, an air layer (space) is formed between the wall of the through hole 136b and the outer surface (side surface) of the first heat conduction member 132. As a result, it is possible to restrain heat transferred through the first heat conduction member 132 from being transferred to the second substrate 18. Consequently, it is possible to suppress the heat transferred through the first heat conduction member 132 from being transferred to the storage unit 20 through the first substrate 14 and the second substrate 18, and restrain the storage unit 20 side from being heated by heat generated in the control unit 22.

From the above description, it may be said that the first heat conduction member 132 is not thermally connected to the first substrate 14 and the second substrate 18. Therefore, in the present embodiment, the amount of heat diffused (radiated) to the second cover 12b (case) may be larger than the amount of heat diffused to the first substrate 14 and the second substrate 18 by employing the first heat conduction member 132.

In this manner, according to the semiconductor device 130, heat generated in the control unit 22 is transferred to the second cover 12b through the first heat conduction member 132 and is radiated therefrom. As a result, the heat radiation of the control unit 22 is efficiently performed, and deterioration in functions of the control unit 22 and reduction in the life span thereof due to heat can be suppressed. In addition, since the heat generated in the control unit 22 may be efficiently radiated, the heat generated in the control unit 22 and transferred towards the storage unit 20 is reduced. Thereby, it is possible to suppress deterioration in the function of the storage unit 20 and a reduction in the life span thereof.

FIG. 3 illustrates an example in which the heat conduction pad 134 is formed on the fourth surface 22h of the control unit 22 and is in contact with the first heat conduction member 132 passing through the second substrate 18. In another embodiment, the heat conduction pad 134 may be formed on the second surface 18a of the second substrate 18, and heat generated in the control unit 22 may be transferred towards the second cover 12b through the first heat conduction member 132, which is thermally connected (adhered) to the heat conduction pad 134.

In this case, heat generated by the storage unit 20 and is transferred through the second substrate 18 may be transferred towards the second cover 12b using the first heat conduction member 132, together with heat generated in the control unit 22. In other words, it is possible to improve the heat radiation efficiency of the element 16 by transferring heat generated by the entire element 16 towards the second cover 12b.

### Second Embodiment

FIG. 7 is a cross-sectional view of a semiconductor device 140 according to a second embodiment. The semiconductor device 140 is a modification example of the semiconductor device 130 according to the first embodiment, and a first heat conduction member 132 is thermally connected to a second wall 12f of a second cover 12b through a second heat conduction member 142. The other configurations are the same as those of the semiconductor device 130 according to the first embodiment, and thus a detailed description thereof will be omitted.

The first heat conduction member 132 is thermally connected to a heat conduction pad 134 in which the tenth surface 132a is formed on a fourth surface 22h of a control unit 22. In addition, the first heat conduction member 132 passes through a second substrate 18 and a first substrate 14, and an eleventh surface 132b is exposed to a rear surface 14b of the first substrate 14. The eleventh surface 132b may slightly protrude from the rear surface 14b. The second heat conduction member 142 is disposed between the rear surface 14b of the first substrate 14 and a second wall 12f of the second cover 12b in a compressed state.

The second heat conduction member 142 is formed of a synthetic resin material (silicone rubber, elastomer, flexible resin) and has, for example, a block shape (rectangular parallelepiped shape, cubic shape). The second heat conduction member 142 has a twelfth surface 142a which is larger than a through hole 136a and is in contact with an eleventh surface 132b of the first heat conduction member 132 and the rear surface 14b.

A thickness H1 of the second heat conduction member 142 is slightly larger than a distance H between the rear surface 14b and the second wall 12f which are formed when the first substrate 14 is fixed to the second cover 12b using, for example, a screw (H1=H+β). As illustrated in FIG. 7, the first substrate 14 supporting an element 16 is fixed to the second cover 12b, and the second heat conduction member 142 is pressed against the second wall 12f by the first substrate 14 and compressed.

In other words, the second heat conduction member 142 is deformed and is adhered to the first heat conduction member 132, and is also adhered to the second wall 12f. As a result, the second heat conduction member 142 may efficiently transfer heat, which is generated in the control unit 22 and is transferred through the first heat conduction member 132, to the second cover 12b and may radiate the heat through the second cover 12b.

In addition, since the second heat conduction member 142 has flexibility, even when an external force is applied to the second cover 12b, the second heat conduction member 142 may absorb the external force. As a result, it is possible to restrain an external force by the second cover 12b from acting on the first heat conduction member 132 and the control unit 22. Meanwhile, the second heat conduction member 142 may include a filler such as carbon in order to improve thermal conductivity.

In this manner, according to the semiconductor device 140, heat generated in the control unit 22 is transferred to the second cover 12b through the first heat conduction member 132 and the second heat conduction member 142 and is radiated therefrom. As a result, the heat radiation of the control unit 22 is efficiently performed, and deterioration in the function of the control unit 22 and reduction in the life span thereof due to the heat generated in the control unit 22 can be suppressed. In addition, since the heat generated in the control unit 22 may be efficiently radiated, the possibility of the heat generated in the control unit 22 being transferred towards the storage unit 20 is reduced. Thereby, it is possible to suppress deterioration in the function of the storage unit 20 and a reduction in the life span thereof due to the heat generated in the control unit 22.

In the present embodiment, the first heat conduction member 132 does not necessarily pass through the first substrate 14. For example, the first heat conduction member 132 may pass through only the second substrate 18 and the eleventh surface 132b of the first heat conduction member 132 may be in contact with the first surface 14a of the first substrate 14.

In this case, heat generated in the control unit 22 is radiated from the eleventh surface 132b through the first heat conduction member 132 to the first substrate 14. The radiated heat flows to the second heat conduction member 142 from the rear surface 14b of the first substrate 14, and is finally transferred to the second cover 12b and is radiated therefrom.

As described above, in the present embodiment, if the heat generated from the control unit 20 is mainly transferred to the second cover 12b, the first heat conduction member 132 does not necessarily pass through the first substrate 14 and the second substrate 18.

### Third Embodiment

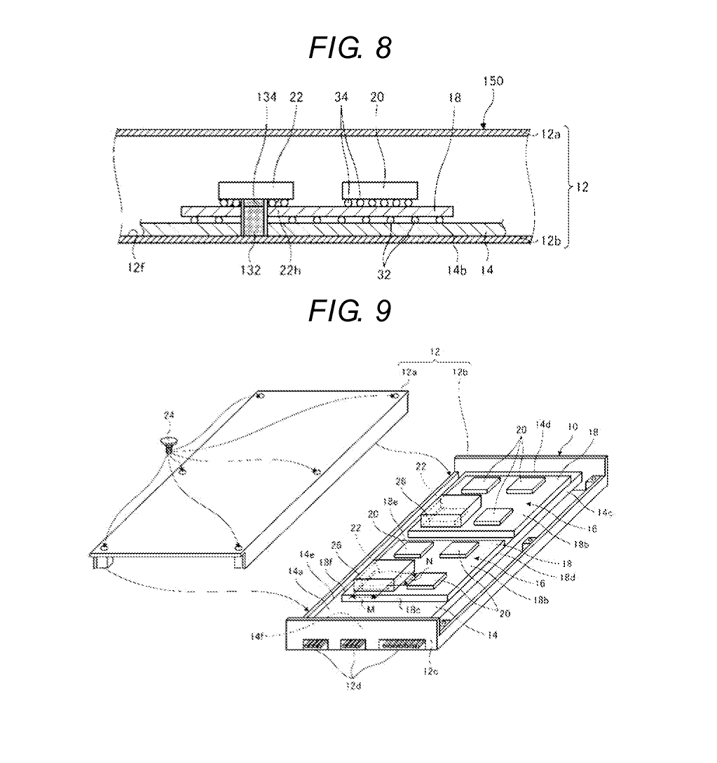

FIG. 8 is a cross-sectional view of a semiconductor device 150 according to a third embodiment. The semiconductor device 150 is a modification example of the semiconductor device 140 according to the second embodiment. For example, the configurations of a heat conduction pad 134 formed on a fourth surface 22h and a first heat conduction member 132 connected thereto are the same as those in the semiconductor device 140. Accordingly, heat transfer using the first heat conduction member 132 is similarly performed, and heat generated by a control unit 22 is transferred to a case 12 and is radiated therefrom.

In the semiconductor device 150, a first substrate 14 supporting an element 16 is fixed in a state where the first substrate 14 is in contact with a second wall 12f of a second cover 12b, and the first substrate 14 and the second cover 12b are thermally connected to each other. As described above, the heat generated in the control unit 22 is transferred to the second cover 12b through the first heat conduction member 132. In addition, heat generated by the storage unit 20 is transferred to a second substrate 18 through bumps 34, and further to the first substrate 14 through a bump 32. Since the first substrate 14 is in contact with the second wall 12f, the heat generated by the storage unit 20 and transferred to the first substrate 14 is transferred to the second cover 12b through the second wall 12f and radiated from the second cover 12b.

In this manner, according to the semiconductor device 150, the heat generated in the control unit 22 is transferred to the second cover 12b through the first heat conduction member 132 and is radiated therefrom. As a result, the heat radiation of the control unit 22 is efficiently performed, and thus it is possible to suppress deterioration in the function of the control unit 22 and a reduction in the life span thereof due to the heat generated in the control unit 22. In addition, since the first substrate 14 is fixed in a state where the first substrate is in contact with the second wall 12f, it is possible to efficiently transfer the heat generated by the storage unit 20 to the second cover 12b and radiate the heat. As a result, it is possible to suppress deterioration in the function of the storage unit 20 and a reduction in the life span thereof due to the heat generated by the storage unit 20.

### Fourth Embodiment

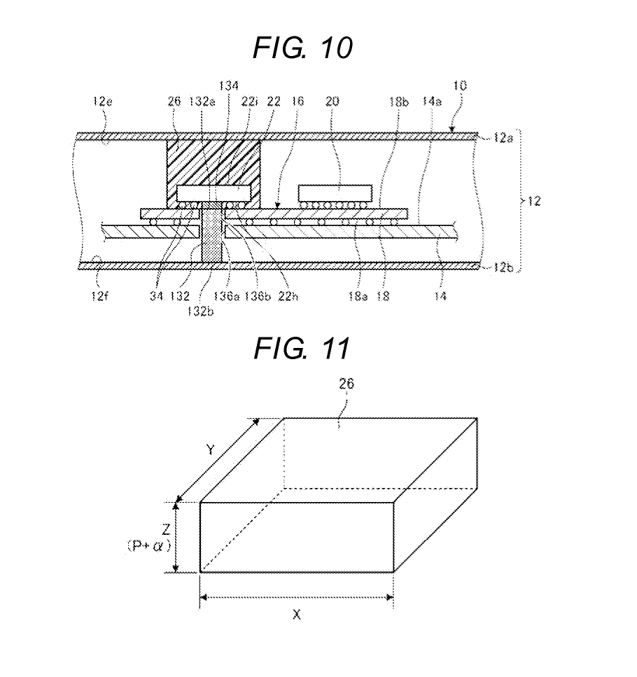

FIG. 9 is a perspective view of a semiconductor device according to a fourth embodiment. FIG. 10 is a cross-sectional view of the semiconductor device 10 according to the fourth embodiment. In the semiconductor device 10, a third heat conduction member 26 is thermally connected (contact, adhered) to a control unit 22, and heat generated in the control unit 22 is transferred to a first cover 12a side and is radiated therefrom. Since the other configurations are the same as those of the semiconductor device 130 according to the first embodiment, a detailed description thereof will be omitted.

In the semiconductor device 10 according to the present embodiment, the control unit 22 has a third heat conduction member 26, in addition to a first heat conduction member 132. The third heat conduction member 26 is formed of a flexible (pliable) material. As illustrated in FIG. 11, the third heat conduction member 26 is formed of, for example, a synthetic resin material (silicone rubber, elastomer, flexible resin) and has, for example, a block shape (rectangular parallelepiped shape, cubic shape).

As illustrated in FIG. 9, the third heat conduction member is disposed between the control unit 22 and a first cover 12a. The first cover 12a and a second cover 12b are fixed to each other, and thus the third heat conduction member 26 is pressed against the control unit 22 by the first cover 12a and is compressed. As a result, the third heat conduction member 26 is deformed and is adhered to the control unit 22 and the first cover 12a. It is possible to efficiently transfer heat generated in the control unit 22 to the first cover 12a and to radiate the heat through the first cover 12a. The third heat conduction member 26 may include a filler such as carbon in order to improve thermal conductivity.

The portion of the third heat conduction member 26 which is in contact with the control unit 22 is flat. For example, it is assumed that the portion of the third heat conduction member 26 which is in contact with the control unit 22 has a recessed hollow portion into which the control unit 22 is fit. When the control unit 22 is fit into the hollow portion, air may remain between the hollow portion and the control unit 22.

On the other hand, in the present embodiment, the portion of the third heat conduction member 26 which is in contact with the control unit 22 is flat. In this case, when the control unit 22 and the first heat conduction member 132 are in contact with each other, air is not likely to remain therebetween. In this state, since the third heat conduction member 26 is compressed, air is not likely to remain on the contact surface therebetween as compared to the case where the hollow portion is formed. As a result, a reduction in thermal conductivity caused when the third heat conduction member 26 is in contact with the control unit 22 is suppressed in the present embodiment.

As illustrated in FIGS. 9 and 10, the third heat conduction member 26 is arranged so as to cover the control unit 22 and a region of a third surface 18b in the vicinity thereof. Further, the first heat conduction member 132 is disposed between the third surface 18b, the control unit 22, and a case 12 in a compressed state. That is, the third heat conduction member 26 includes an eighth surface 26a that is in contact with at least a fifth surface 22i of the control unit 22 and the third surface 18b and a ninth surface 26b that is in contact with a first wall 12e of the first cover 12a.

In FIG. 10, the area (X*Y in FIG. 11) of the eighth surface 26a of the third heat conduction member 26 is larger than the area (M*N in FIG. 9) of the fifth surface 22i of the control unit 22. In addition, the thickness (dimension in the thickness direction, dimension in the insertion direction, Z in FIG. 11) of the third heat conduction member 26 in a free state where the third heat conduction member is not held between the third surface 18b, the control unit 22, and the second cover 12b (case) is larger by a compression-expected dimension a than a distance P (a dimension in the thickness direction (insertion direction) when the third heat conduction member is held between the third surface 18b, the control unit 22, and the second cover 12b) between the first wall 12e of the first cover 12a and the third surface 18b of the second substrate 18 when the first substrate 14 having an element 16 fixed thereto is fixed to the second cover 12b and the first cover 12a is fixed to the second cover 12b using a fastening member 24 (Z=P+a).

In other words, the third heat conduction member 26 may contract by its own flexibility. Meanwhile, a deformation rate in a case where the third heat conduction member 26 is compressed between the first cover 12a and the second substrate 18 (control unit 22) and the magnitude of a pressing force against the first wall 12e and the fifth surface 22i which is generated by compressing the third heat conduction member 26 are measured in advance through examination or the like, and the compression-expected dimension a may be appropriately selected in accordance with the size of the distance P. As the third heat conduction member 26 has flexibility, even when an external force acts on the first cover 12a, the third heat conduction member 26 absorbs the external force. Thus, it is possible to restrain an external force from being applied to the control unit 22.

In this manner, the third heat conduction member 26 having flexibility is compressed when being held between the first cover 12a and the second substrate 18 (control unit 22), and thus the eighth surface 26a of the third heat conduction member 26 adheres to the fifth surface 22i of the control unit 22. As a result, it is possible to efficiently transfer heat generated by the control unit 22 to the third heat conduction member 26. Similarly, the ninth surface 26b of the third heat conduction member 26 adheres to the first wall 12e of the first cover 12a, and thus heat transferred to the third heat conduction member 26 may be further transferred to the first cover 12a and may be radiated through the first cover 12a.

According to the present embodiment, heat generated in the control unit 22 is transferred by directly adhering to the eighth surface 26a of the third heat conduction member 26 to the fifth surface 22i of the control unit 22 which is a bare chip. For this reason, the number of layers disposed up to the first cover 12a is decreased as compared to a case where the control unit 22 is covered with a covering portion such as a resin, and it is possible to suppress a reduction in heat transfer efficiency. As a result, the heat radiation of the control unit 22 may be efficiently performed in spite of an increase in a frequency used in the control unit 22, and thus it is possible to suppress deterioration in the function (performance) of the control unit 22 and a reduction in the life span thereof which are caused by the heat generated in the control unit 22.

In addition, since heat may be efficiently transferred toward the first cover 12a from the control unit 22, it is possible to reduce the amount of heat transferred to the second substrate 18 through bumps 34. In other words, it is possible to restrain heat generated in the control unit 22 from being transferred to the storage unit 20 through the second substrate 18. As a result, it is possible to restrain the storage unit 20 generating heat during the operation thereof from being further heated by external heat. Therefore, it is possible to suppress deterioration in the function (performance) of the storage unit 20 and a reduction in the life span thereof, which are caused by the heat generated in the control unit 22.

Meanwhile, in the example of FIG. 10, the third heat conduction member 26 covers the control unit 22 and a portion of the third surface 18b in the vicinity thereof. As a result, even when a portion of heat generated in the control unit 22 is transferred to the second substrate 18 side through the bumps 34, the heat may be transferred to the first cover 12a through the third heat conduction member 26. Even with this configuration, it is possible to improve efficiency for transferring heat generated in the control unit 22 to the first cover 12a.

Further, when heat generated by the storage unit 20 is transferred to the second substrate 18 through the bumps 34, it is possible to transfer the heat to the first cover 12a through the third heat conduction member 26. As a result, it is possible to restrain the heat generated by the storage unit 20 from being transferred to the control unit 22 and heating the control unit 22 or from being transferred to another storage unit 20 and heating the storage unit. In other words, it is possible to suppress deterioration in the functions of the control unit 22 and the storage unit 20 and a reduction in the life span thereof due to the heat transferred through the second substrate 18.

Meanwhile, the third heat conduction member 26 may include a non-conductive magnetic material which does not transfer radio waves. For example, a filler such as ferrite may be mixed with a synthetic resin material configuring the first heat conduction member 132. With such a filler, it is possible to prevent electromagnetic impact on the control unit 22 by covering the control unit 22 with the third heat conduction member 26 including a non-conductive magnetic material. As a result, it is possible to further stabilize the operation of the control unit 22. In addition, the third heat conduction member 26 may be provided with adhesiveness (adhesive force) in order to facilitate operation while mounting the third heat conduction member to the semiconductor device 10.

For example, when the third heat conduction member 26 is formed of silicone rubber or the like, it is possible to obtain necessary adhesive properties by changing a composition ratio between a silicone rubber component and a silicone resin component. Since the third heat conduction member 26 may be temporarily fixed (attached) to at least one of the first wall 12e of the first cover 12a and the control unit 22, for example, while holding the third heat conduction member 26 between the control unit 22 and the first cover 12a using the adhesiveness of the third heat conduction member 26, it is possible to improve assembling efficiency.

The adhesiveness (adhesive force) may be maintained for a period of time required for at least the assembling, but the adhesive force may be maintained permanently. In addition, the adhesive force may be an adhesive force to such an extent that the third heat conduction member 26 may be easily attached and released. In this case, positioning while temporarily fixing the third heat conduction member 26 and the repositioning thereof are facilitated, and thus it is possible to improve workability.

In addition, when temporary fixing to the first wall 12e is performed by providing adhesiveness to the third heat conduction member 26, it is not necessary to use a separate adhesive or the like. When an adhesive or the like is disposed between the third heat conduction member 26 and the first cover 12a or the control unit 22, the number of interfaces and layers is increased, which may result in a reduction in thermal conductivity.

On the other hand, as in the present embodiment, the third heat conduction member 26 itself has an adhesive property. As the formation of an unnecessary layer is suppressed, it is possible to suppress a reduction in thermal conductivity. In the present embodiment, the third heat conduction member 26 has a rectangular parallelepiped shape according to the shape of the control unit 22, but the embodiment is not limited thereto. For example, the third heat conduction member may have, for example, a polygonal column shape or a cylindrical shape, as long as the third heat conduction member may cover the control unit 22 and the same effects may be obtained.

In the present embodiment, the third heat conduction member 26 is particularly described in detail, but the same principle and configuration may be applied to the first heat conduction member 132 and the second heat conduction member 142 that are described in the first to third embodiments.

With the above-described configuration, in the semiconductor device 10 according to the present embodiment, heat generated in the control unit 22 is transferred to the second cover 12b through the first heat conduction member 132 and is radiated therefrom, and is transferred to the first cover 12a through the third heat conduction member 26 and is radiated therefrom.

As a result, the heat radiation in the control unit 22 is efficiently performed, and it is possible to suppress deterioration in the function of the control unit 22 and reduction in the life span thereof by heat. In addition, since the heat generated in the control unit 22 may be efficiently radiated, amount of the heat generated in the control unit 22 transferred towards the storage unit 20 is reduced. Thereby, it is possible to suppress deterioration in the function of the storage unit 20 and reduction in the life span thereof, which are caused by the heat generated in the control unit 22.

### Fifth Embodiment

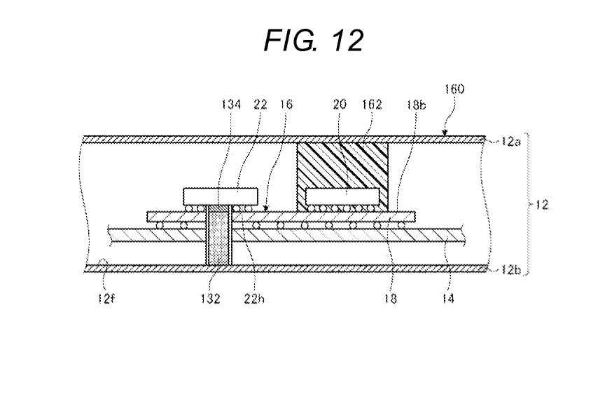

FIG. 12 is a cross-sectional view of a semiconductor device 160 according to a fifth embodiment. The semiconductor device 160 is a modification example of the semiconductor device 10 according to the fourth embodiment. In the semiconductor device 160, the third heat conduction member 26 of the semiconductor device 10 is omitted. That is, the semiconductor device 160 transfers heat generated by a control unit 22 to a second cover 12b through a first heat conduction member 132 which is thermally connected to the heat conduction pad 134 formed on a fourth surface 22h of the control unit 22. Such a configuration is effective, for example, when it is not desirable to transfer heat generated in the control unit 22 to a first cover 12a.

Meanwhile, in the case of FIG. 12, a fourth heat conduction member 162 covers the storage unit 20. Similarly to the third heat conduction member 26, the fourth heat conduction member 162 is formed of, for example, a synthetic resin material (silicone rubber, elastomer, flexible resin) and has, for example, a block shape (a rectangular parallelepiped shape, a cubic shape). The fourth heat conduction member is disposed between the storage unit 20 and the first cover 12a.

The first cover 12a and the second cover 12b are fixed to each other, and the fourth heat conduction member 162 is pressed against the storage unit 20 by the first cover 12a and compressed. As a result, the fourth heat conduction member 162 is deformed and adhered to the storage unit 20 and the first cover 12a. As a result, it is possible to efficiently transfer heat generated by the storage unit 20 to the first cover 12a and radiate the heat through the first cover 12a.

The fourth heat conduction member 162 may include a filler formed of a material such as carbon, in order to improve thermal conductivity. In addition, the fourth heat conduction member 162 may include a non-conductive magnetic material which does not transfer radio waves, for example, ferrite, to prevent electromagnetic impact on the storage unit 20. In addition, the fourth heat conduction member 162 itself may have an adhesive property.

Similarly to the first heat conduction member 132, by employing the fourth heat conduction member 162 that transfers heat generated by the storage unit 20, the same effects as the first embodiment may be obtained. For example, when the second cover 12b is desired to radiate heat generated in the control unit 22 and the first cover 12a is desired to radiate heat generated in the control unit 22, that is, when heat radiation is desired to be performed separately, the above-described configuration may be preferably employed.

As described above, in the semiconductor device 150, heat generated by the storage unit 20 that does not include the fourth heat conduction member 162 may be transferred to the second cover 12b through the first substrate 14, or may be radiated into a case 12 and may be radiated to the outside of the case 12 using, for example, an air blower (fan).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate having a first surface and a second surface opposite to the first surface, a hole formed through the first and second surfaces of the substrate;
a semiconductor element disposed on the first surface to cover the hole;
a housing in which the substrate and the semiconductor element are housed; and
a heat conduction member disposed in the hole, such that heat generated by the semiconductor element is transferred through the heat conduction member towards a portion of the housing facing the second surface of the substrate.

2. The semiconductor device according to claim 1, wherein
the heat conduction member is in contact with the portion of the housing.

3. The semiconductor device according to claim 1, wherein
the heat conduction member is in contact with the semiconductor element.

4. The semiconductor device according to claim 1, further comprising:
a connecting member disposed between the semiconductor element and the heat conduction member.

5. The semiconductor device according to claim 1, wherein
the heat conduction member is integrally formed with the housing.

6. The semiconductor device according to claim 1, wherein
the housing includes a protrusion that protrudes towards an inner space of the housing, and
the heat conduction member is in contact with the protrusion.

7. The semiconductor device according to claim 1, further comprising:
a semiconductor memory unit disposed on the first surface of the substrate adjacent to the semiconductor element, wherein
the semiconductor element is a controller configured to control the semiconductor memory unit.

8. The semiconductor device according to claim 7, wherein
a position of the hole is offset from a center of the semiconductor element towards the semiconductor memory unit.

9. The semiconductor device according to claim 1, wherein
the semiconductor element is a semiconductor memory unit.

10. The semiconductor device according to claim 1, wherein
the heat conduction member is spaced apart from an inner surface of the hole.

11. The semiconductor device according to claim 1, further comprising:
a second substrate on which the substrate is mounted and having a hole penetrating therethrough, wherein
the heat conduction member is also disposed in the hole of the second substrate.

12. The semiconductor device according to claim 1, wherein
the heat conduction member is formed of an elastic material and pressed between the semiconductor element and the housing.

13. The semiconductor device according to claim 1, wherein
an end of the heat conduction member facing the housing is adhesive.

14. The semiconductor device according to claim 1, wherein
an end of the heat conduction member facing the semiconductor element is adhesive.

15. The semiconductor device according to claim 1, further comprising:
a second heat conduction member disposed between the first surface of the substrate and the housing and enclosing the semiconductor element.

16. The semiconductor device according to claim 15, wherein
the second heat conduction member is formed of an elastic material and pressed between the semiconductor element and the housing.

17. A method for transferring heat generated in a semiconductor device including a substrate, a semiconductor element disposed on a first surface of the substrate, and a housing in which the substrate and the semiconductor element are housed, the method comprising:
transferring heat generated by the semiconductor element towards a portion of the housing facing a second surface of the substrate opposite to the first surface, through a heat conduction member disposed in a hole formed in the substrate.

18. The method according to claim 17, further comprising:
transferring the heat generated by the semiconductor element towards a portion of the housing facing the first surface of the substrate, through a second heat conduction member disposed between the first surface of the substrate and the housing.

19. The method according to claim 17, wherein
the semiconductor device further includes a semiconductor memory unit disposed on the first surface of the substrate adjacent to the semiconductor element, and
the semiconductor element is a controller configured to control the semiconductor memory unit.

20. The method according to claim 17, wherein
the semiconductor element is a semiconductor memory unit.
